(19) United States
(12) Patent Application Publication
(10) Pub. No.: US 2007/0049072 A1
(43) Pub. Date: Mar. 1, 2007

(54) Board mount connector suitable for automatic mounting

(75) Inventor: Yukiko Sato, Tokyo (JP)

Correspondence Address: WILLIAM COLLARD;COLLARD & ROE, P.C., 1077 NORTHERN BOULEVARD, ROSLYN, NY, 11576, US

(73) Assignee: JAPAN AVIATION ELECTRONICS INDUSTRY, LIMITED, Tokyo (JP)

(21) Appl. No.: 11/509,487

(22) Filed: Aug. 24, 2006

(30) Foreign Application Priority Data
Aug. 25, 2005 (JP) 2005-243712

(51) Int. Cl. H05K 1/00

(52) U.S. Cl. 439/79

(57) ABSTRACT

In a connector to be mounted to a board having a pair of first through holes and at least one second through hole, a pair of supporting portions is formed on a housing holding a plurality of contacts arranged in a first direction. Each of the supporting portions protrudes from the housing in a second direction perpendicular to the first direction. First bosses protrude from the supporting portions to be inserted into the first through holes, respectively. At least one second boss is coupled to the housing to be inserted into the at least one second through hole.

This application claims priority to prior Japanese patent application JP 2005-243712, the disclosure of which is incorporated herein by reference.

### BACKGROUND OF THE INVENTION

This invention relates to a connector to be mounted to a board.

As a connector of the type, a connector having a coupling surface parallel to a board and generally high in profile is known (for example, see Japanese Utility Model Registrations Nos. 2500036 and 2549644). The connector comprises a housing made of an insulating material, a number of contacts arranged in parallel to one another at a predetermined pitch and held by the housing, and a shell covering the housing. The housing is provided with an expanded lower portion formed at its lower part. The housing is provided with a boss having a generally rectangular section and formed at a lower center part thereof. The shell is also provided with a plurality of bosses each having a generally rectangular section and formed at a lower part thereof. When these bosses are inserted into through holes of the board, the contacts are connected to contact point patterns of the board. In this state, a mating connector can be connected to the connector.

In order to prevent the connector from falling down when it is mounted to the board, the connector is provided with, for example, the expanded lower portion formed at its bottom. In this case, however, the connector is increased in size and can not meet the demand for a compact structure.

Alternatively, the bosses of the connector may be press-fitted into the through holes of the board. In this case, however, the connector must be pushed so that the bosses are fitted into the through holes. Therefore, depending upon the type of the connector, it is impossible to automatically mount the connector to the board.

Alternatively, the connector is fixed to the board by the use of a hook. In this case, however, the connector is increased in size and can not meet the demand for a compact structure.

### SUMMARY OF THE INVENTION

It is therefore an object of this invention to provide a connector suitable to be mounted to a board by an automatic mounting machine.

It is another object of this invention to provide a compact connector.

It is still another object of this invention to provide a connector which is prevented from falling down when it is mounted to a board.

Other objects of the present invention will become clear as the description proceeds.

According to an aspect of the present invention, there is provided a connector to be mounted to a board having a pair of first through holes and at least one second through hole, the connector comprising a housing, a plurality of contacts arranged in a first direction and held by the housing, a pair of supporting portions formed on the housing and protruding from the housing in a second direction perpendicular to the first direction, a pair of first bosses protruding from the supporting portions to be inserted into the first through holes, respectively, and at least one second boss coupled to the housing to be inserted into the at least one second through hole.

### BRIEF DESCRIPTION OF THE DRAWING

FIG. 1 is a front perspective view of a connector according to an embodiment of this invention when it is mounted to a board;

FIG. 2 is a rear perspective view of the connector in FIG. 1 when it is mounted to the board;

FIG. 3 is a plan view of the connector in FIG. 1 when it is mounted to the board;

FIG. 4 is a side view of the connector in FIG. 1 when it is separated from the board;

FIG. 5 is a side view of the connector in FIG. 1 when R is mounted to the board;

FIG. 6 is a view for describing a dimensional relationship of characteristic parts of the connector and the board; and

FIG. 7 is a view for describing a state where the connector is inclined at a predetermined angle with respect to the board.

### DESCRIPTION OF THE PREFERRED EMBODIMENT

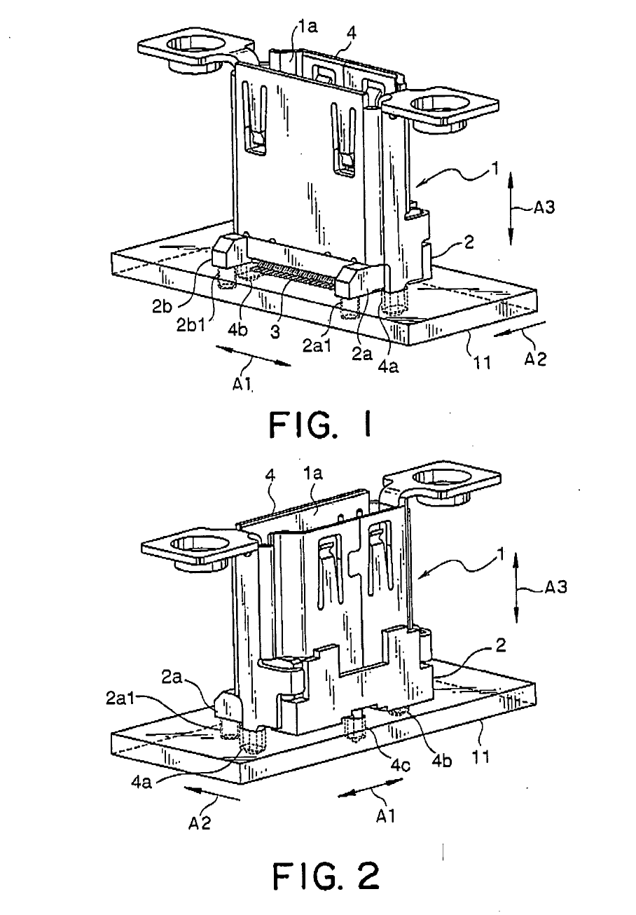

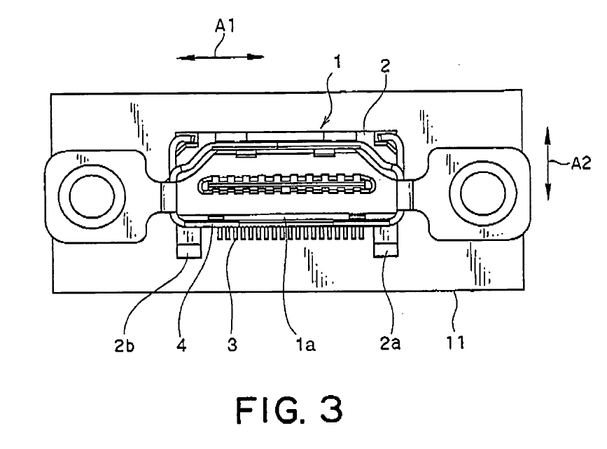

Referring to FIGS. 1 through 3, a connector according to an embodiment of this invention will be described.

The connector depicted at 1 in the figure comprises a housing 2 made of an insulating material such as plastic, a number of conductive contacts 3 arranged in parallel to one another at a predetermined pitch in a first direction (left-and-right direction) A1 and held by the housing 2, and a shell 4 made of metal and covering the contacts 3 and the housing 2.

The housing 2 is provided with a pair of, namely, two expanded lower portions 2a and 2b formed as supporting portions at a lower front part thereof. The expanded lower portions 2a and 2b are spaced from each other in the first direction A1 and protrude in a second direction (back-and-forth direction) A2 perpendicular to the first direction A1. The expanded lower portions 2a and 2b are provided with bosses 2a1 and 2b1 having a circular section and formed on their bottom surfaces, respectively. Each of the bosses 2a1 and 2b1 will be called a first boss.

The shell 4 is provided with bosses 4a and 4b formed at a lower center part thereof in the second direction A2. The bosses 4a and 4b are spaced from each other in the first direction A1 and have a rectangular section. The shell 4 is further provided with a boss 4c formed at its lower center part on a rear side. The boss 4c has a rectangular section and called a second boss. Each of the bosses 4a and 4b will be called a third boss.

The connector 1 is mounted to a board 11, for example, by an automatic mounting machine. The contacts 3 are connected to contact point patterns (not shown) of the board 11 by soldering or the like. The connector 1 has a coupling slot 1a adapted to receive a connecting portion of a mating connector (not shown). When the mating connector is coupled to the coupling slot 1a, the mating connector is contacted with the contacts 3 and electrically connected to the contact point patterns of the board 11 through the contacts 3. It is noted here that the connector 1 has a relatively large height from the board 11 in a third direction (ups-and-downs direction) A3 perpendicular to the first and the second directions A1 and A2.

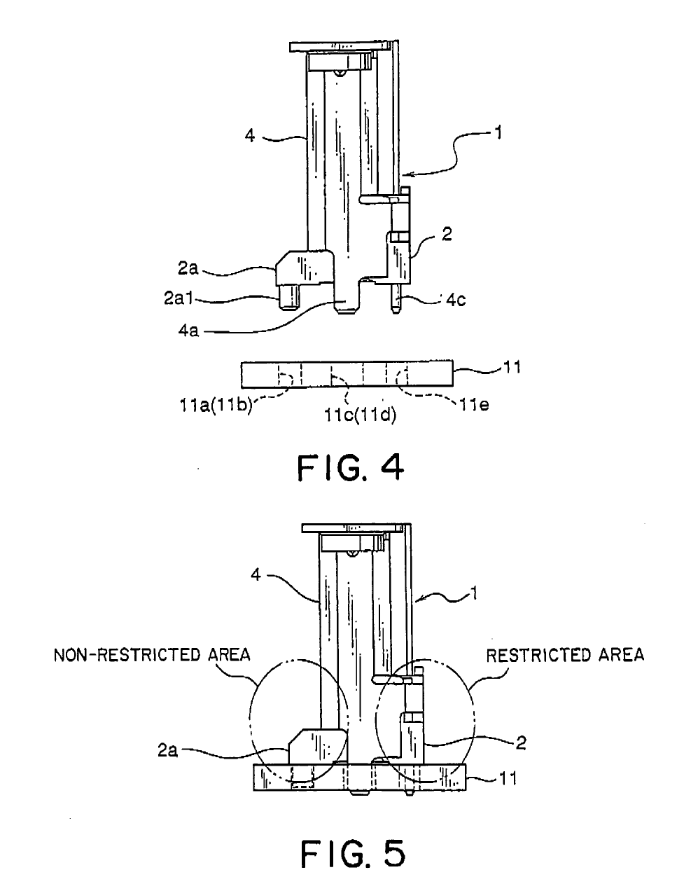

Referring to FIGS. 4 and 5 in addition, description will be made of a relationship between the connector 1 and the board 11.

The board 11 is provided with a plurality of through holes penetrating the board 11 in a vertical direction. The through holes include two through holes 11a and 11b having a circular shape, formed at a relatively front part, and spaced from each other in the first direction A1, two through holes 11c and 11b having a rectangular shape, formed at a center part, and spaced from each other in the first direction A1, and a through hole 11e having a rectangular shape and formed at a relatively rear part.

In order to mount the connector 1 to the board 11, the bosses 2a1, 2b1, 4a, 4b, and 4c of the connector 1 are faced to the through holes 11a, 11b, 11c, 11d, and 11e of the board 11 as shown in FIG. 4, respectively. Thereafter, the connector 1 is moved down so that the bosses 2a1, 2b1, 4a, 4b, and 4c are inserted into the through holes 11a, 11b, 11c, 11d, and 11e of the board 11, respectively. This state is called a provisional mounted state. In the provisional mounted state, the connector 1 is not fixed to the board 11 and can be inclined. Thereafter, the contacts 3 are connected to the contact point patterns of the board 11 and the connector 1 is fixed to the board 11 by appropriate means. Thus, a mounted state illustrated in FIG. 5 is obtained.

Herein, it is assumed that a “non-restricted area” and a “restricted area” are present around the connector 1 where the expanded lower parts can be formed and can not be formed, respectively. In case where the connector 1 is attached to an end portion of the board 11, an upper region above the end portion is the “restricted area” while an upper region of the board 11 on an opposite side of the connector 1 is the “non-restricted area”. In case where other electronic parts are mounted to the board 11 to be adjacent to one side of the connector 1, a region where the electronic parts are disposed and its peripheral region are the “restricted area” while an upper region of the board 11 on the other side of the connector 1 is the “non-restricted area”. Specifically, in FIG. 5, it is assumed that a region around a front side of the connector 1 is the “non-restricted area” while a region around a rear side of the connector 1 is the “limited area”. Therefore, the expanded lower portions 2a and 2b are formed only on the front side of the connector 1 and no expanded lower portions are formed on the rear side. Thus, the connector 1 can be formed into a relatively compact structure.

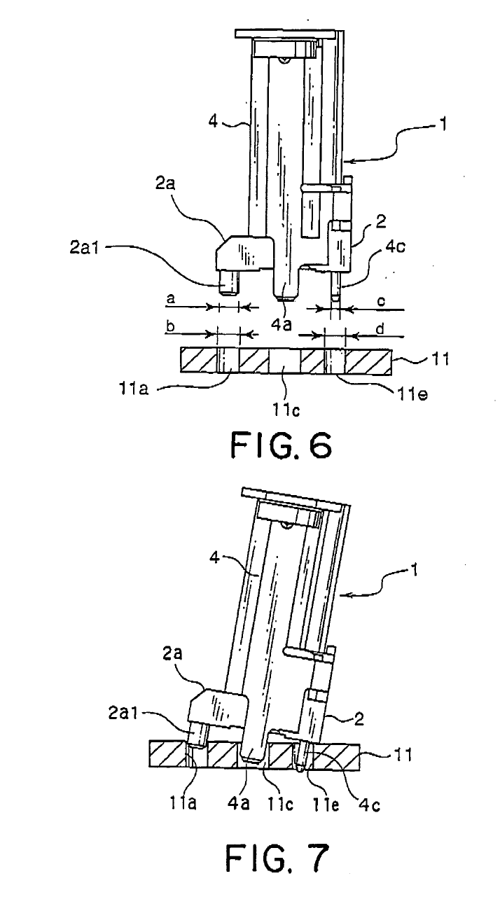

Referring to FIGS. 6 and 7 in addition, description will be made of a dimensional relationship between the bosses 2a1, 2b1, 4a, 4b, and 4c of the connector 1 and the through holes 11a, 11b, 11c, 11d, and 11e of the board 11 as well as an effect achieved by the dimensional relationship.

In FIG. 6, the bosses 2a1 and 2b1 have a same diameter a. The through holes 11a and 11b have a same diameter b slightly greater than the diameter a. The boss 4c has a diameter c. The through hole 11e has a diameter d slightly greater than the diameter c. For example, the diameters a through d are determined as follows. However, the diameters b and d may be equal to each other.

a=1.2 mm

b=1.4 mm

c=0.5 mm

d=0.65 mm

The bosses 4a and 4b are smaller in diameter than the through holes 11c and 11d. However, the relationship therebetween need not strictly be met because of the following reason. That is, assuming that the connector 1 is inclined in the provisional mounted state as shown in FIG. 7, the bosses 4a and 4b serve as the center of rotation upon inclination. Therefore, the dimensional relationship between the bosses 4a and 4b and the through holes 11c and 11d need not strictly be met.

Since the bosses 2a1, 2b1, 4a, 4b, and 4a of the connector 1 are smaller in diameter than the through holes 11a, 11b, 11c, 11d, and 11e of the board 11, respectively, it is easy to insert the bosses into the through holes. Therefore, it is easily possible to mount the connector 1 to the board 11 by the use of the automatic mounting machine.

When the connector 1 is inclined to a predetermined angle in the provisional mounted state as illustrated in FIG. 7, the bosses 2a1 and 2b1 interfere with inner surfaces of the through holes 11a and 11b while the boss 4c interferes with an inner surface of the through hole 11e. As a result, the connector 1 is prevented from being inclined beyond the predetermined angle. Therefore, an operation of connecting the contacts 3 to the contact point patterns of the board 11 is not inhibited.

The bosses 4a and 4b and the through holes 11c and 11d are designed so that, even if the connector 1 is inclined to the predetermined angle, the bosses 4a and 4b do not interfere with inner surfaces of the through holes 11c and 11d. However, the bosses 4a and 4b and the through holes 11c and 11d may be designed so that the bosses 4a and 4b interfere with the inner surfaces of the through holes 11c and 11d.

Further, even with the first bosses 2a1 and 2b1 and the second boss 4c without the third bosses 4a and 4b, the connector 1 can achieve the desired object.

Although this invention has been described in conjunction with the preferred embodiment thereof, this invention may be modified in various other manners. Although a single second boss is illustrated, the housing may be provided with two or more second bosses. In this event, it is a matter of course that the board is added with through holes in response to addition of the second boss.

What is claimed is:

1. A connector to be mounted to a board having a pair of first through holes and at least one second through hole, the connector comprising:
a housing;
a plurality of contacts arranged in a first direction and held by the housing;
a pair of supporting portions formed on the housing and protruding from the housing in a second direction perpendicular to the first direction;
a pair of first bosses protruding from the supporting portions to be inserted into the first through holes, respectively; and
at least one second boss coupled to the housing to be inserted into the at least one second through hole.

2. The connector according to claim 1, further comprising a shell coupled to the housing, the at least one second boss being integrally formed with the shell.

3. The connector according to claim 2, wherein the housing is made of plastic and the shell is made of metal.

4. The connector according to claim 1, wherein the board has a pair of third through holes, the connector having a pair of third bosses formed between the first bosses and the second boss in the second direction to be inserted into the third through holes, respectively.

5. The connector according to claim 4, further comprising a shell coupled to the housing, the third bosses being integrally formed with the shell.

6. The connector according to claim 5, wherein at least one second boss is integrally formed with the shell.

7. The connector according to claim 4, wherein the housing is made of an insulating material and the shell is made of metal.

8. The connector according to claim 1, wherein the first bosses are smaller in diameter than the first through holes.

9. The connector according to claim 1, wherein the at least one second boss is smaller in diameter than the at least one second through hole.

10. The connector according to claim 1, wherein the first bosses extend in a third direction perpendicular to the first and the second directions and are smaller in diameter than the first through holes, the at least one second boss extending in the third direction and smaller in diameter than the at least one second through hole.
